(19) United States
(12) Patent Application Publication
(10) Pub. No.: US 2021/0270885 A1
(43) Pub. Date: Sep. 2, 2021

(54) METHOD FOR SUPPRESSING FAULT PHASE RESIDUAL VOLTAGE OF RESONANT GROUNDING SYSTEM BASED ON PRECISE TUNING CONTROL ON ACTIVE ADJUSTABLE COMPLEX IMPEDANCE

(71) Applicant: HANGZHOU QIUCHUANG ELECTRIC POWER SCIENCE & TECHNOLOGY CO., LTD., Hangzhou City (CN)

(72) Inventor: Guiyu YANG, Hangzhou City (CN)

(21) Appl. No.: 17/244,968

(22) Filed: Apr. 30, 2021

Related U.S. Application Data
(63) Continuation of application No. PCT/CN2019/076033, filed on Feb. 25, 2019.

(30) Foreign Application Priority Data
Nov. 1, 2018 (CN) 201811295297.3

(51) Int. Cl. G01R 31/08; G01R 31/52; G01R 27/26; G01R 27/18

(52) U.S. Cl. CPC G01R 31/086; G01R 27/18; G01R 27/2605; G01R 31/52

(57) ABSTRACT

A method for suppressing fault phase residual voltage of a resonant grounding system based on precise tuning control on active adjustable complex impedance is provided, and the method tracks a fault phase-to-ground voltage in real-time, uses active adjustable complex impedance to change a reactance current injected by a neutral point, and uses complex phasor proportional and integral links to control a current of the active adjustable complex impedance, to perform precise tuning control on a zero-sequence loop, to make it enter a highly resonant state, and in this case, both a fault phase-to-ground voltage and a grounding current will be effectively suppressed, and deviations caused by links such as a grounding resistance in a station, an internal resistance of an arc suppression coil, and unbalanced admittance of a line-to-ground will be accurately compensated.

### TECHNICAL FIELD

The present disclosure relates to a control method for single-phase grounding fault voltage of a resonant grounding system and, more particularly, to a method for suppressing fault phase residual voltage of a resonant grounding system based on precise tuning control on active adjustable complex impedance, specifically, including tracking measurement of a target electrical quantity and a closed-loop tuning control method of an active controlled arc suppression inductor.

### BACKGROUND

A key to the resonant grounding system is that a current flowing through ground reactance of a neutral point must be exactly equal to a three-phase ground distribution capacitance current, to make arc suppression reactance and line distribution capacitance be connected in parallel and be in resonance, to realize that the fault phase-to-ground voltage is lowest, and a theoretical value thereof is 0V. Due to complex operating conditions of a power distribution network, it is difficult to accurately measure line distribution capacitance and conductance parameters, so it is impossible to accurately set arc suppression reactor parameters in advance. In addition, it is difficult for reactance equipment to achieve continuous adjustment of parameters, and there is a minimum level difference in a pre-adjusted arc suppression device; a phase-controlled arc suppression device uses half-wave internal chopping to achieve tracking adjustment, which has problems such as adjustment delay and chopping harmonics. Therefore, the control method that relies on zero-sequence parameter measurement results and sets the arc suppression reactance parameters always has deviations, and after the arc suppression device operates, there will always be a certain residual voltage and ground residual current between the fault phase grounding point and the ground.

In recent years, a number of documents have proposed further compensation and control methods for ground residual voltage and residual current, including Document 1 (“Safety Treatment Method for Active Voltage drop of Grounding fault Phase of Ineffective Grounding System”, Patent Application Number: 201710550400.3), Document 2 (“Method for Arc Suppression and Protection of Grounding faults in Distribution Networks”, Patent Application Number: 201110006701.2), Document 3 (“Arc Suppression Method for Flexible Grounding Device Based on Dual Closed Loop Control”, Electric Power Journal of Science and Technology, Vol. 30 No. 4, December, 2015.P63-70), and Document 4 (“Active Intervention Arc Suppression Line Selection Device for Distribution Network”, Patent Application No. 201720846940. 1), etc.

The method provided in the Document 1 requires use of a multi-tap grounding transformer, uses a method of adjusting taps to find the minimum operating point of the fault phase residual voltage, an active voltage drop branch adopts impedance buffering, a phase selection test is performed, to avoid grounding shock generated after false judgment. This method complicates the equipment, and it is not suitable for direct resonance grounding of the distribution transformer, the operation of the active voltage drop branch is threatened, and the residual voltage and residual current are not limited, and it is only used as a protective measure.

Document 2 proposes to use an injection current method to make the fault phase-to-ground voltage be zero, which is a characteristic of a traditional arc suppression grounding system under precise resonance, however, a setting expression (see paragraph [0016]) of an injected target current contains a line zero-sequence capacitance C0 and an insulation resistance r0, which are unknown parameters and cannot be accurately measured, and it lacks a dynamic control strategy to make the voltage-to-ground zero. The injection current also does not consider influence of active power consumption such as a grounding resistance in a station, an internal resistance of an arc suppression coil, and an internal resistance of a grounding transformer winding, and it lacks compensation for active components. In paragraph [0031], only a fault phase voltage is used as a target boost value of a neutral point voltage, there is not only phase voltage measurement deviation, in addition, consumption such as the grounding resistance and the line conductance cannot be effectively compensated, so the residual voltage and residual current to the ground cannot be converged to zero. Moreover, in paragraph [0052], it is inappropriate to determine a phase having the lowest ground voltage as the fault phase, and it must be determined according to an offset method of the neutral point. In addition, no residual pressure data is provided in this document.

Document 3 is an extension of Document 2, a dual-loop control method tries to solve the lack of a control strategy in Document 2, however, active factors such as grounding resistance in a station are still not considered in a system equation, and the inappropriate phase determination method in Document 2 is used. Considering a role of the closed-loop control loop, when increasing an amplitude of a neutral point voltage to a fault phase voltage, it can compensate for a part of active disturbance, however, the zero residual pressure convergence problem described in paragraph [0031] of the aforementioned Document 2 still exists. Comparing simulation conclusions of Document 2 and Document 3, the method did not obtain better residual current convergence results. In addition, this document does not provide residual pressure data.

Document 4 is a typical scheme of an active intervention method, this scheme avoids the problems of arc suppression grounding and matching resonance operating points, and instead, it uses a direct grounding scheme on a bus side of the fault phase to try to direct flow in a station. However, due to the existence of grounding resistance, an effect of directing flow can only be divided by impedance. If a long line is fully loaded, the line voltage drop will have an impact on the fault grounding current, and the directing flow effect will be worse in the case of a metallic or low resistance grounding fault. Actively intervening high-speed switching brings about problems such as rising costs, increased complexity, and phase-to-phase short-circuit protection, and there are risks when phase selection is wrong.

In some applications, a scheme of combining an arc suppression coil and active intervention is proposed, and a residual voltage effect will be significantly reduced, however, no matter from a perspective of directing flow or a resonance state, the convergence problem of the residual voltage and the residual current cannot be solved. Not to mention problems and risks of the active intervention.

Using an inductive current of traditional arc suppression grounding to make the zero-sequence loop resonate and reduce the ground residual voltage is a widely accepted method. However, the problem of zero-sequence parameter measurement, the problem of precise tuning of an inductor current, and the problem of compensation of the resistive component of a system must be well resolved, only in this way the loop can enter the precise resonance state, and the fault phase-to-ground reaches zero residual voltage, which is an ideal grounding state pursued under the resonance grounding mode of this type of power distribution system.

### SUMMARY

In view of the shortcomings in the related art, an object of the present disclosure is to provide a method for suppressing fault phase residual voltage of a resonant grounding system based on precise tuning control on active adjustable complex impedance.

The present disclosure tracks a fault phase-to-ground voltage in real-time, changes, using the active adjustable complex impedance, a reactance current injected by a neutral point, and controls a current of the active adjustable complex impedance using complex phasor proportion integration to perform the precise tuning control on a zero-sequence loop.

Specifically, the method adopts a conventional resonance grounding method, the neutral point N is grounded through a branch on which an arc suppression inductor L, an equivalent resistance R and a controllable inverter source unit \dot{U}ₓ are connected in series, and an adjustable current İ_{X} is injected into the neutral point; a fractional value L₀/m of a standard arc suppression reactance L₀ is taken as an injection branch reactance L, and L₀ and C₀ satisfy a resonance condition:

ω²L₀C₀=1,

letting:

$${\dot{U}}_{X} = ( 1 - \frac{1}{m} ) {\dot{U}}_{a} + j ω {C}_{0} {\dot{U}}_{a} R + ( R + j ω L ) {Y}_{0} {\dot{U}}_{a} ,$$

where \dot{U}ₐ denotes a voltage of a fault phase A, C₀ denotes a total zero-sequence capacitance and is a sum of distribution capacitance of three phases, Y₀ denotes a total zero-sequence conductance and is a sum of distribution conductance of the three phases, R_{K} denotes grounding resistance at a fault point K, and ω denotes a power frequency angular frequency of a power distribution network; a negative feedback control loop is construct while taking a fault phase A-to-ground voltage \dot{U}_{AG} as input, taking a neutral point-to-ground voltage \dot{U}_{GN} and a voltage drop of a zero-sequence network current of a system on an injection branch as corrections; an appropriate complex phasor proportion integration parameter cPI[Kp+Ki/s] are taken in such a manner that the zero-sequence loop enters a LC parallel resonance state and a loop input U_{AG} converges to 0 and a fault branch current I_{K} is also 0; a real part and an imaginary part of the input complex phasor are taken as PI control; and a control equation is:

\dot{U}_{\tilde{X}}=\dot{U}_{GN}+(R+jωn(İ_{C0}+İ_{Y0})+cPI[\dot{U}_{AG}(R+jωL)/R_{K}],

where the complex phasor proportion integration is:

cPI[a+jb]=a(Kp+Ki/s)+jb(Kp+Ki/s).

In the above schemes, the total zero-sequence current İ_{C0}+İ_{Y0} of a line and the impedance R_{K} are ignored, and a control equation is simplified as:

\dot{U}_{\tilde{X}}=\dot{U}_{GN}+cPI[\dot{U}_{AG}]

The method of the present disclosure can be implemented in a direct mode; and a compensation inductive current is directly injected into the neutral point, or an isolation transformer is configured to inject an inductive current into the neutral point.

The present disclosure uses the active adjustable complex impedance to change the reactance current injected by the neutral point, by implementing appropriate control strategies, the arc suppression ground reactance branch can be embodied as pure inductance characteristics and form precise resonance with the line zero-sequence equivalent capacitance. Both the fault phase-to-ground voltage and the ground current will be effectively suppressed, and deviations caused by links such as a grounding resistance in a station, an internal resistance of an arc suppression coil, and unbalanced admittance of the line-to-ground will be accurately compensated. This method can maintain stable convergence for the fault phase in high, medium and low resistance grounding faults, and it is a control method that effectively suppresses the fault phase to-ground residual voltage and residual current.

### BRIEF DESCRIPTION OF DRAWINGS

FIG. 1 is a schematic diagram of a three-phase power distribution system and active adjustable complex impedance;

FIG. 2 is an equivalent zero-sequence circuit of a three-phase circuit shown in FIG. 1;

FIG. 3 is an equivalent circuit of the zero-sequence circuit shown in FIG. 2;

FIG. 4 is a negative feedback control loop;

FIG. 5 is a simplest control block diagram of the present disclosure;

FIG. 6 is a control scheme when an existing arc suppression coil X1 is used to provide part of an inductive current;

FIG. 7 is a current curve of a fault branch circuit of a simulation with a 10 kV system and a compensation current of 150 A; and

FIG. 8 shows details of a convergence process.

### DESCRIPTION OF EMBODIMENTS

The present disclosure will be further described below in conjunction with the drawings.

The present disclosure adopts a conventional resonance grounding method, a controllable inverter source unit \dot{U}ₓ is adopted in an arc suppression grounding reactance branch of a neutral point N, an adjustable current İₓ injected into the neutral point through an inductor L, and after implementing a proper control strategy, an arc suppression grounding reactance branch can be embodied as a pure inductance characteristic, and form a precise resonance with a line zero-sequence equivalent capacitance.

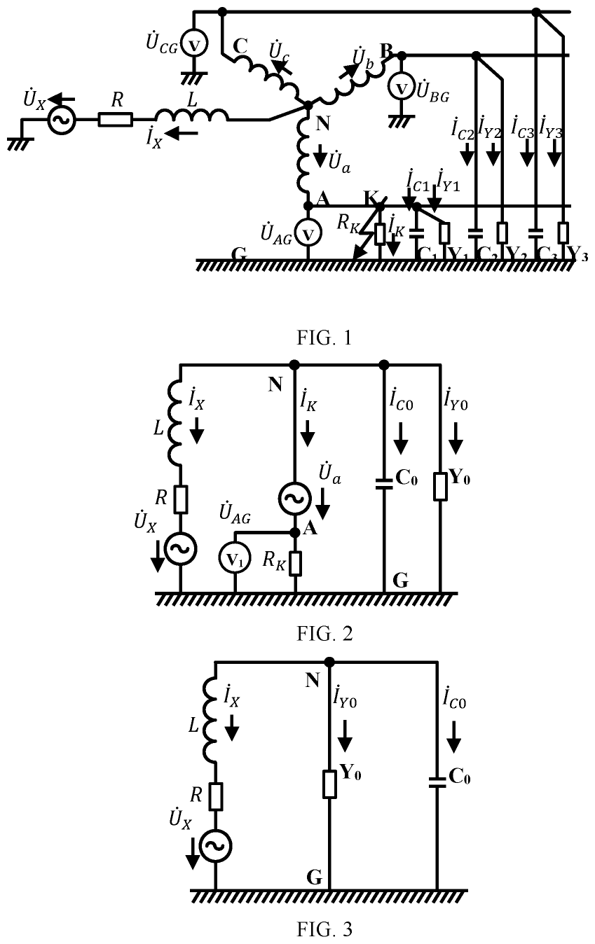

As shown in FIG. 1, the neutral point N of a main transformer (or a zigzag grounding transformer) is grounded through a branch on which an arc suppression inductor L, an equivalent resistance R and the controllable inverter source unit \dot{U}ₓ are connected in series, and the equivalent resistance R is a sum of a coil resistance r and a grounding resistance Rg. Three voltage sensors V1, V2, and V3 are used to measure bus-to-ground voltages \dot{U}_{AG}, \dot{U}_{BG}, \dot{U}_{CG} of three phases respectively, and analysis parameters and reference directions thereof are shown in FIG. 1. Without loss of generality, it is supposed that a phase A is a fault phase, a grounding resistance at a fault point K is R_{K}, line-to-ground distribution capacitance of the three phases are C₁, C₂, and C₃, and grounding conductance are respectively Y₁, Y₂, and Y₃. Here:

İₐ=İ_{C1}+İ_{Y1}=(\dot{U}ₐ−\dot{U}_{GN})(jωC₁+Y₁) (1);

İ_{b}=İ_{C2}+İ_{Y2}=(\dot{U}_{b}−\dot{U}_{GN})(jωC₂+Y₂) (2);

İ_{c}=İ_{C3}+Ī_{Y3}=(\dot{U}_{c}−\dot{U}_{GN})(jωC₃+Y₃) (3);

İ_{X}=−(İₐ+İ_{b}+İ_{c}) (4).

Under symmetrical conditions, the three-phase ground parameters are balanced, and for each phase, the capacitance is C_{φ} and the conductance is Y_{φ}, and the three-phase power supply is also completely symmetrical. When the injection source Uₓ is 0, a neutral point-to-ground voltage U_{GN} is 0, and the current I_{X} is 0.

After a single phase-to-ground fault occurs, the current of the fault phase A branch is:

İₐ=(\dot{U}ₐ−\dot{U}_{GN})(jωC₁+Y₁+1/R_{K}) (5),

the formulas (2), (3), (5) are substituted into the formula (4), and the phase distribution capacitance C_{φ} and the distribution conductance Y_{φ} are substituted, then:

İ_{X}=−(\dot{U}ₐ+\dot{U}_{b}+\dot{U}_{c})(jωC_{φ}+Y_{φ})+3\dot{U}_{GN}(JωC_{φ}+Y_{φ})−(\dot{U}ₐ−\dot{U}_{GN})/R_{K} (6),

that is,

İ_{X}=\dot{U}_{GN}(jω3C_{φ}+3Y_{φ})−(\dot{U}ₐ−\dot{U}_{GN})/R_{K} (7)

According to the formula (7), the three-phase circuit shown in FIG. 1 can be equivalent to a zero-sequence circuit shown in FIG. 2, where a total zero-sequence capacitance C₀ is a sum of the distribution capacitances C₁, C₂, and C₃ of the three phases, that is 3 C_{φ}; a total zero-sequence conductance Y₀ is a sum of the distribution conductance Y₁, Y₂, and Y₃ of the three phases, that is 3Y_{φ}. A voltage measured by the A phase-to-ground measurement voltage V1 is the fault phase-to-ground voltage \dot{U}_{AG}.

The zero-sequence circuit shown in FIG. 2 is controlled so that the terminal voltage \dot{U}_{GN} of the controlled arc suppression grounding branch is exactly equal to a fault phase voltage \dot{U}ₐ, a fault grounding branch current I_{K} will be 0, which is equivalent to that R_{K} is in an open circuit, and the fault phase-to-ground voltage \dot{U}_{AG} is 0. Then, the zero-sequence loop can also be equivalent to a simple loop shown in FIG. 3. In this case, the formula (7) is:

İ_{X}=\dot{U}_{GN}(jω3C_{φ}+3Y_{φ}) (8).

The injection current İ_{X} of the controlled injection branch of the neutral point is:

İ_{X}=(\dot{U}_{X}−\dot{U}_{GN})/(R+jωL) (9),

where \dot{U}_{GN}=\dot{U}ₐ. From the formula (8) and the formula (9), it can be obtained that:

\dot{U}_{X}=[1+(R+jωL)(jωC₀+Y₀)]\dot{U}ₐ (10).

A fractional value L₀/m of the standard arc suppression reactance L₀ is taken as the injection branch reactance L, and L₀ and C₀ meet a resonance condition:

ω²L₀C₀=1 (11).

A value of the fractional reactance and the resonance condition are substituted into the formula (10), then:

$${\dot{U}}_{X} = ( 1 - \frac{1}{m} ) {\dot{U}}_{a} + j ω {C}_{0} {\dot{U}}_{a} R + ( R + j ω L ) {Y}_{0} {\dot{U}}_{a} . \qquad ( 12 )$$

The formula (12) is a controlled condition of an equivalent ideal reactance of the zero-sequence loop, and it can be divided into 3 items: a last term is a negative conductance voltage component, which is used to offset the line distribution conductance Y₀ branch; a middle term is a negative resistance voltage component, which is used to offset a total resistance of the arc suppression injection branch; a first term is an equivalent voltage component of partial reactance to full reactance. Moreover, when the three-phase power distribution system shown in FIG. 1 is injected, the equivalent reactance value is continuously adjustable between capacitive and inductive, and when and only when a residual pressure is 0, the formula (12) satisfies the resonance condition.

If the line conductance is 0, the last term is 0; if the total resistance R of the injection branch is 0, the middle term is 0; if the total reactance is taken, m is 1, then the first term is 0. When the three conditions are met at the same time, a value of the controlled source \dot{U}_{X} is taken 0, the zero-sequence loop degenerates into a pure inductance and capacitance loop, and under excitation of the fault phase voltage, LC oscillation is induced by the fault resistance R_{K}, and an oscillation terminal voltage converges to the fault phase voltage \dot{U}ₐ.

In actual engineering, usually all these three conditions are not satisfied, but as long as values of an amplitude and a phase of the controlled source \dot{U}_{X} are taken according to the formula (12), the three-phase loop shown in FIG. 1 can obtain accurate resonance conditions, so that the residual voltage at the fault phase grounding point is zero. Similarly, if there is a control method that makes the residual voltage of the fault phase grounding point 0, then, the controlled source \dot{U}_{X} must satisfy the condition of the formula (12), and the loop is in a precise resonance state. Here, the injection branch shown in FIG. 1 can be referred to as “active adjustable complex impedance”.

From the formula (7), there are:

İ_{X}=(\dot{U}_{X}−\dot{U}_{GN})/(R+jωL)=\dot{U}_{GN}(jωC₀+Y₀)−(\dot{U}ₐ−\dot{U}_{GN})/R_{K} (13),

\dot{U}_{X}=\dot{U}_{GN}+(R+jωL)(jωC₀+Y₀)\dot{U}_{GN}−\dot{U}_{AG}(R+jωL)/R_{K} (14), and

\dot{U}_{X}=\dot{U}_{GN}−(R+jωL)(İ_{C0}+İ_{Y0})−\dot{U}_{AG}(R+jωL)/R_{K} (15),

where each parameter takes the reference direction shown in FIG. 2.

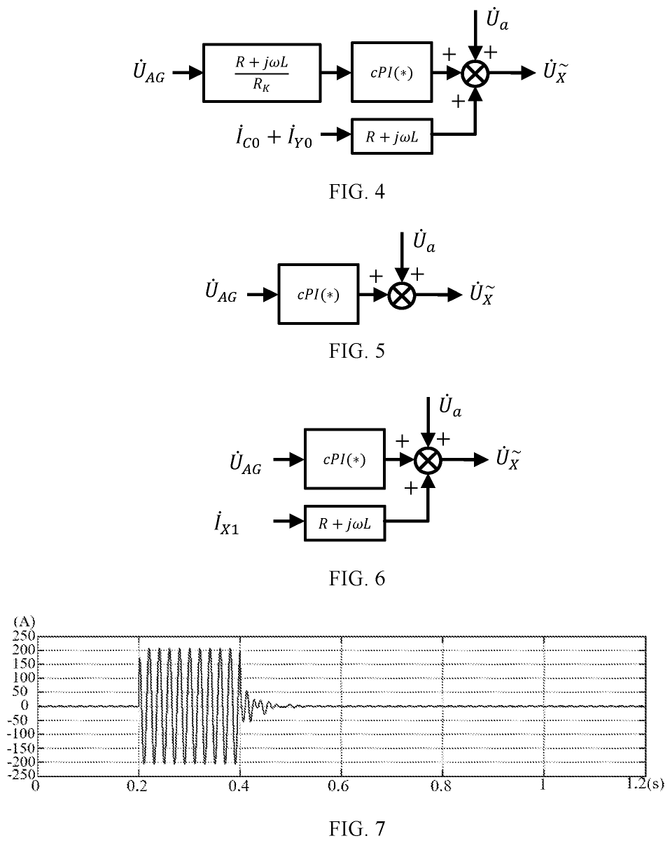

According to the formula (15), the present disclosure proposes a following solution: a negative feedback control loop is to established and shown in FIG. 4 while taking the fault phase-to-ground voltage \dot{U}_{AG} as input, taking the neutral point-to-ground voltage \dot{U}_{GN} and a voltage drop of the system zero-sequence network current on the injection branch as corrections and taking an appropriate complex phasor proportion integration parameter cPI[Kp+Ki/s] (see the formula 17), such that the zero-sequence loop can enter a LC parallel resonance state, a loop input U_{AG} converges to 0, and the fault branch current I_{K} is also 0. The real and imaginary parts of the input complex phasor are both subjected to PI control calculations. A control equation is as follows:

\dot{U}_{\tilde{X}}=\dot{U}_{GN}+(R+jωL)(I_{C0}+I_{Y0})+cPI[\dot{U}_{AG}(R+_jωL)/R_{K}] (16),

where the complex phasor proportional integral link is:

cPI[a+jb]=a(Kp+Ki/s)+jb(Kp+Ki/s) (17).

In the formula (16), the total zero-sequence current İ_{C0}+İ_{Y0} of the line is a complex constant under a resonance convergence condition, and a measured value is affected by the convergence process of the ground voltage \dot{U}_{AG}. If the ground voltage \dot{U}_{AG} converges reliably, this term can be taken as a complex constant having deviation, or even ignored, and compensated by the cPI link. It is noted that an impedance ratio (R+jωL)/R_{K} of the injection branch and the fault grounding branch contains the unknown impedance R_{K}, this will affect setting of the cPI gain, and it can be processed in sections according to the neutral point voltage offset. By ignoring these two parameters, then there is the simplest control expression (18), and the control block diagram is as shown in FIG. 5.

\dot{U}_{\tilde{X}}=\dot{U}_{GN}+cPI[\dot{U}_{AG}] (18).

The stability of the control system is investigated by the formula (14) and the formula (18):

$$\begin{matrix}{\dot{U}}_{X} = {\dot{U}}_{G N} + ( R + j ω L ) ( j ω {C}_{0} + {Y}_{0} ) {\dot{U}}_{G N} - {\dot{U}}_{A G} ( R + j ω L ) / {R}_{K} , & ( 14 ) \\ {\dot{U}}_{\tilde{X}} = {\dot{U}}_{G N} + cPI [ {\dot{U}}_{A G} ] , and & ( 18 ) \\ [ ( R + j ω L ) ( j ω {C}_{0} + {Y}_{0} ) ] ( {\dot{U}}_{a} - {\dot{U}}_{A G} ) - \frac{R + j ω L}{{R}_{K}} {\dot{U}}_{A G} - cPI [ {\dot{U}}_{A G} ] = 0 , & ( 19 )\end{matrix}$$

a s-domain equation thereof is:

$$\begin{matrix}[ ( R + s L ) ( s {C}_{0} + {Y}_{0} ) ] ( {\dot{U}}_{a} - {\dot{U}}_{A G} ) - \frac{R + s L}{{R}_{K}} {\dot{U}}_{A G} - ( {K}_{p} + \frac{{K}_{i}}{s} ) {\dot{U}}_{A G} = 0 , \\ and & ( 20 ) \\ {\dot{U}}_{A G} = [ 1 - \frac{{s}^{2} L / {R}_{K} + s ( R / {R}_{K} + {K}_{p} ) + K i}{\begin{matrix}{s}^{3} L {C}_{0} + {s}^{2} ( R {C}_{0} + L {Y}_{0} + L / {R}_{K} ) + \\ s ( R {Y}_{0} + R / {R}_{K} + {K}_{p} ) + {K}_{i}\end{matrix}} ] {\dot{U}}_{a} , & ( 21 )\end{matrix}$$

a characteristic formula of the control system is:

s³LC₀+s²(RC₀+LY₀+L/R_{K})+s(RY₀+R/R_{K}+Kₚ)+Kᵢ=0 (22).

Considering a resonant grounding system with a capacity of 150 A: approximately taking three relative-to-ground capacitors of 28 μF, C₀ is 84 μF; taking that the resonant connection inductance L is 15 mH; Y₀ is taken as three times the single-phase conductance of 1 μS: 3 μS; R is 4Ω; and R_{K} is 1Ω.

The characteristic equation has three complex roots: (−5.01+j0), (−604.64+j1896.47), (−604.64−j1896.47), all of which converge. Then letting R_{K} be grounded at 10Ω, 100Ω, 1000Ω, 10000Ω, or even not grounded, all reliably converge, that is, the fault phase-to-ground voltage converges to 0.

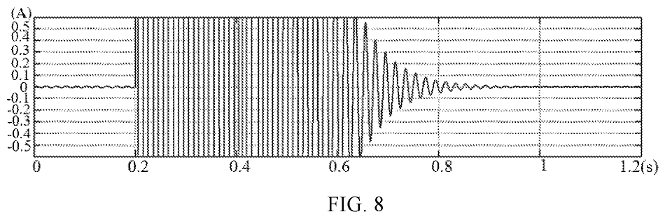

Simulation results: FIG. 7 shows the current curve of the fault branch circuit of a simulation having the 10 kV system and the compensation current of 150 A, the A phase line has a single-phase grounding fault at 0.2 second, and the grounding resistance is 1052, the control system starts at 0.4 second and basically converges at about 0.5 seconds. FIG. 8 shows details of the convergence process.

Test result: in two resonant grounding test systems having a line voltage of 173V, an arc suppression capacity of 100V4.5 A/450 VA and a line voltage 400V, an arc suppression capacity of 230V45 A/10 kVA, this scheme has the same conclusion, and convergence transition time is 3 to 5 power frequency cycles. When calculated according to a capacitance nominal value, compensation deviation of the inductive current at resonance is about 5‰, a residual voltage reading of a working frequency voltmeter is 0V, and the control system outputs about 50 mV in real time.

It can be seen that this solution combines the problems of zero residual voltage convergence target, precise resonance condition setting, and compensation of active components into one control system, and through appropriate closed-loop feedback control, several problems can be solved at the same time. It is particularly important that the measurement of the fault phase-to-ground voltage is a zero voltage measurement, and the zero detection accuracy of a voltage sensor is much higher than the non-zero measurement accuracy. These are the advantages of this program.

The control scheme proposed by the patent of the present disclosure can be implemented in a direct mode, that is, the compensation inductive current is directly injected into the neutral point, or an isolation transformer can be used to inject the inductive current into the neutral point. Whether an isolation transformer is used or not has no essential impact on this scheme.

When using the existing arc suppression coil X1 to provide part of the inductive current, the present disclosure proposes the control scheme of FIG. 6, İₓᵢ can be the measured current of partial reactance under an effect of \dot{U}_{GN}, and it can also approximately adopt a calculated current under an effect of the fault phase voltage \dot{U}ₐ, which does not affect the system convergence.

For a similar control scheme constructed by the scheme proposed by the present disclosure, if its fundamental nature has not changed significantly, it is also within the scope of the present disclosure.

What is claimed is:

1. A method for suppressing fault phase residual voltage of a resonant grounding system based on precise tuning control on active adjustable complex impedance, comprising:
tracking a fault phase-to-ground voltage in real-time;
changing, using the active adjustable complex impedance, a reactance current injected by a neutral point; and
controlling a current of the active adjustable complex impedance using complex phasor proportion integration, to perform the precise tuning control on a zero-sequence loop.

2. The method for suppressing the fault phase residual voltage of the resonant grounding system based on the precise tuning control on the active adjustable complex impedance according to claim 1, wherein the method adopts a conventional resonance grounding method, the neutral point N is grounded through a branch on which an arc suppression inductor L, an equivalent resistance R and a controllable inverter source unit \dot{U}ₓ are connected in series, and an adjustable current İ_{X} is injected into the neutral point; a fractional value L₀/m of a standard arc suppression reactance L₀ is taken as an injection branch reactance L, and L₀ and C₀ satisfy a resonance condition:
ω²L₀C₀=1,
letting:
$${\dot{U}}_{X} = ( 1 - \frac{1}{m} ) {\dot{U}}_{a} + j ω {C}_{0} {\dot{U}}_{a} R + ( R + j ω L ) {Y}_{0} {\dot{U}}_{a} ,$$
where \dot{U}ₐ denotes a voltage of a fault phase A, C₀ denotes a total zero-sequence capacitance and is a sum of distribution capacitance of three phases, Y₀ denotes a total zero-sequence conductance and is a sum of distribution conductance of the three phases, R_{K} denotes grounding resistance at a fault point K, and ω denotes a power frequency angular frequency of a power distribution network;
a negative feedback control loop is established while taking a fault phase A-to-ground voltage \dot{U}_{AG} as input, taking a neutral point-to-ground voltage \dot{U}_{GN} and a voltage drop of a zero-sequence network current of a system on an injection branch as corrections; an appropriate complex phasor proportion integration parameter cPI[Kp+Ki/s] are taken in such a manner that the zero-sequence loop enters a LC parallel resonance state and a loop input U_{AG} converges to 0 and a fault branch current I_{K} is also 0; a real part and an imaginary part of the input complex phasor are taken as PI control; and a control equation is:
\dot{U}_{\tilde{X}}=\dot{U}_{GN}+(R+jωL)(i_{C0}+I_{Y0})+cPI[\dot{U}_{AG}(R+jωL)/R_{K}],
where the complex phasor proportion integration is:
cPI[a+jb]=a(Kp+Ki/s)+jb(Kp+Ki/s).

3. The method for suppressing the fault phase residual voltage of the resonant grounding system based on the precise tuning control on the active adjustable complex impedance according to claim 2, wherein the total zero-sequence current İ_{C0}+İ_{Y0} of a line and the impedance R_{K} are ignored, and a control equation is simplified as:
\dot{U}_{\tilde{X}}=\dot{U}_{GN}+cPI[\dot{U}_{AG}].

4. The method for suppressing the fault phase residual voltage of the resonant grounding system based on the precise tuning control on the active adjustable complex impedance according to claim 2, wherein the method is implemented in a direct mode; and
a compensation inductive current is directly injected into the neutral point, or an isolation transformer is configured to inject an inductive current into the neutral point.
